(19) United States
(12) Patent Application Publication
(10) Pub. No.: US 2011/0207256 A1
(43) Pub. Date: Aug. 25, 2011

(54) IN-SITU ACCEPTOR ACTIVATION WITH NITROGEN AND/OR OXYGEN PLASMA TREATMENT

(75) Inventor: Jie Su, Santa Clara, CA (US)

(73) Assignee: APPLIED MATERIALS, INC., Santa Clara, CA (US)

(21) Appl. No.: 13/031,563

(22) Filed: Feb. 21, 2011

Related U.S. Application Data
(60) Provisional application No. 61/307,514, filed on Feb. 24, 2010.

(51) Int. Cl. H01L 21/20; C23C 16/34; C23C 16/50

(52) U.S. Cl. 438/46; 118/723 R; 257/E21.09

(57) ABSTRACT

Embodiments of the present invention generally relate to methods and apparatus for the manufacturing of devices, such as light emitting diodes (LEDs), laser diodes (LDs) and, more particularly, to processes for forming Group III-V materials by metal-organic chemical vapor deposition (MOCVD) processes. In one embodiment, a method for fabricating a compound nitride structure on a substrate is provided. The method comprises depositing a p-type doped Group III-nitride film over one or more substrates in a processing chamber and exposing the p-type doped Group III-nitride film to a plasma in the processing chamber to activate the p-type dopant by breaking up hydride complexes formed between the p-type dopant and hydrogen.

### CROSS-REFERENCE TO RELATED APPLICATIONS

This application claims benefit of U.S. provisional patent application Ser. No. 61/307,514 (Attorney Docket No. 14794L), filed Feb. 24, 2010, which is herein incorporated by reference in its entirety.

### BACKGROUND OF THE INVENTION

1. Field of the Invention

Embodiments of the present invention generally relate to methods and apparatus for the manufacturing of devices, such as light emitting diodes (LEDs), laser diodes (LDs) and, more particularly, to processes and apparatus for forming Group III-V materials by metal-organic chemical vapor deposition (MOCVD) processes.

2. Description of the Related Art

Group III-V films are finding greater importance in the development and fabrication of a variety of semiconductor devices, such as short wavelength light-emitting diodes (LEDs), laser diodes (LDs), and electronic devices including high power, high frequency, high temperature transistors and integrated circuits. For example, short wavelength (e.g., blue/green to ultraviolet) LEDs are fabricated using the Group III-nitride semiconducting material gallium nitride (GaN). It has been observed that short wavelength LEDs fabricated using GaN can provide significantly greater efficiencies and longer operating lifetimes than short wavelength LEDs fabricated using non-nitride semiconducting materials, comprising Group II-VI elements.

One method that has been used for depositing Group III-nitrides, such as gallium nitride (GaN), is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface. In certain embodiments, dopants may be added to the process to form a p-type doped Group III-nitride layer, for example, magnesium doped Group III-nitride.

For the magnesium doped Group III-nitride, the highly resistive behavior of the as grown layer causes several problems. Two possible mechanisms have been proposed for this highly resistive behavior. The first mechanism is so called self-compensation caused by the formation of Mg_{Ga}—V_{N} due to the nitrogen vacancy, which acts as a donor for Group III-nitrides such as GaN. The second mechanism, involves the passivation of magnesium acceptors by hydrogen to form electrically inactive Mg—H complexes.

Highly conductive and low resistivity p-type GaN may be achieved by various known techniques, including low energy electron beam irradiation (LEEBI) processes and thermal annealing under nitrogen. Both techniques are believed to break the Mg—H complexes and reduce compensation of the N-vacancy. Other techniques have also been reported, such as, using plasma enhanced chemical vapor deposition (PECVD) deposited silicon oxide (SiOₓ) cap layer followed by subsequent thermal annealing, low-temperature activation with thin metallic films (Ni, Co, Pt), radiation by excimer-laser or X-ray, and ex-situ post-growth plasma-assisted activation (PAA) using oxygen and nitrogen. However, most of these techniques involve ex-situ activation which occurs after film growth. Ex-situ activation processes often involve additional steps which increase the processing time per substrate and consequently the cost of ownership. Ex-situ activation processes may also involve exposure of the as-deposited film to the atmosphere which can lead to contamination and degradation of the film.

As the demand for LEDs, LDs, transistors, and integrated circuits increases, the efficiency of depositing high quality Group-III nitride films takes on greater importance. Therefore, there is a need for improved methods and apparatus for fabricating a compound nitride structure on a substrate

### SUMMARY OF THE INVENTION

Embodiments of the present invention generally relate to methods and apparatus for the manufacturing of devices, such as light emitting diodes (LEDs), laser diodes (LDs) and, more particularly, to processes and apparatus for forming Group III-V materials by metal-organic chemical vapor deposition (MOCVD) processes. In one embodiment, a method for fabricating a compound nitride structure on a substrate is provided. The method comprises depositing a p-type doped Group III-nitride film over one or more substrates in a processing chamber and exposing the p-type doped Group III-nitride film to plasma in the processing chamber to activate the p-type dopant by breaking up hydride complexes formed between the p-type dopant and hydrogen. The plasma may be formed from a gas source selected from the group consisting of: O₂, N₂, O₂/N₂, N₂O, NO, and combinations thereof.

In another embodiment, a method for fabricating a compound nitride structure on a substrate is provided. The method comprises depositing a magnesium doped gallium nitride (GaN) film over one or more substrates in a metal organic chemical vapor deposition (MOCVD) chamber and exposing the magnesium doped GaN film to a nitrogen containing plasma in the MOCVD chamber to activate the magnesium dopant by breaking up magnesium-hydride complexes formed between magnesium and hydrogen.

In yet another embodiment, an integrated processing system for fabricating a compound nitride structure on a substrate is provided. The integrated processing system comprises a transfer chamber, a robot assembly disposed in the transfer chamber for transferring one or more substrates without exposing the one or more substrates to atmosphere, a metal organic chemical vapor deposition (MOCVD) chamber in transferable communication with the transfer chamber and operable to form a p-type doped Group III-nitride film over one or more substrates with a thermal chemical-vapor-deposition process, and a remote plasma source coupled with the MOCVD chamber for delivering a nitrogen containing plasma to the MOCVD chamber to activate the p-type dopant by breaking up hydride complexes formed between the p-type dopant and hydrogen.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a structure of a GaN-based LED formed according to embodiments described herein;

FIG. 2 is a schematic top view illustrating one embodiment of a processing system for fabricating compound nitride semiconductor devices according to embodiments described herein;

FIG. 3 is a schematic cross-sectional view of one embodiment of a metal-organic chemical vapor deposition (MOCVD) chamber for fabricating compound nitride semiconductor devices according to embodiments described herein; and

FIG. 4 is a flow diagram of one embodiment of an in-situ acceptor activation process that may be used for in-situ acceptor activation with either nitrogen and/or oxygen plasma treatment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to in-situ acceptor activation with plasma treatment for p-type doped Group III-nitrides films, such as magnesium doped GaN and related alloys, for example, indium-gallium-nitride (InGaN), aluminum-gallium-nitride (AlGaN), and aluminum-indium-gallium-nitride (AllnGaN). The embodiments described herein can also be used for other Group III-V compound semiconductors, in which the doping acceptor species exhibit the phenomena of H₂-passivation and usually require thermal annealing for the activation of dopants. In certain embodiments described herein, in-situ acceptor activation is performed via plasma treatment using N₂, O₂, or N₂/O₂ mixture. In certain embodiments, the plasma of interest is generated by remote inductively coupled plasma connected to the processing chamber. In embodiments where the p-type dopant is magnesium, the Mg—H bonds can be broken by the plasma energy, and hydrogen can be effectively removed in the presence of O₂ to form H₂O. In certain embodiments, the proposed method can be carried out at lower temperatures, for example, below the growth temperature or typical N₂ thermal annealing temperature which is generally around 700-800 degrees Celsius. In certain embodiments, the p-type doped Group III-nitride films are first exposed to N₂ followed by exposure to O₂ or O₂ mixture. In certain embodiments, additional thermal or plasma annealing under N₂ is required to repair any possible plasma damage. In certain embodiments, growth of the p-type doped Group III-nitride film and the plasma treatment occur in-situ within the same chamber.

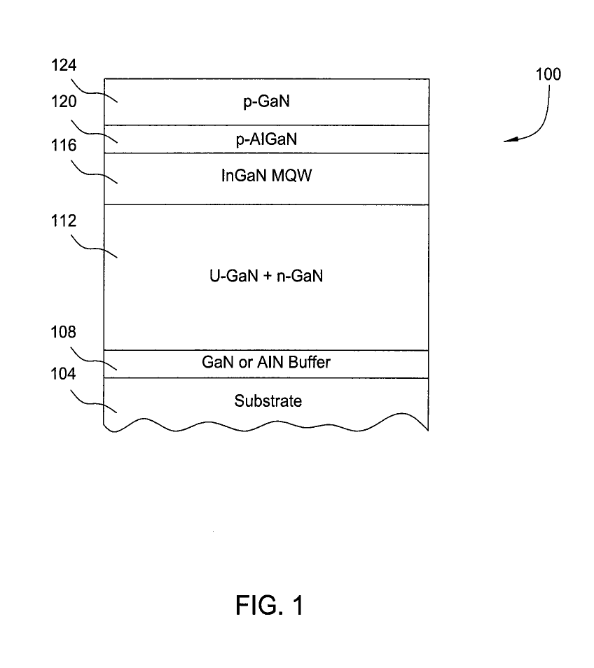

Currently, MOCVD and HVPE techniques are the most widely used techniques for the growth of Group III-nitride based LED manufacturing. One example of a nitride-based structure that may be formed using any combination of MOCVD and/or HVPE techniques is illustrated in FIG. 1 as a GaN-based LED structure 100. In one embodiment, the GaN-based LED structure is fabricated over a sapphire substrate 104. Substrate size may range from 50 mm-100 mm in diameter or larger. The substrate carrier size may range from 200 mm-500 mm. The substrate carrier may be formed from a variety of materials, including SiC or SiC-coated graphite. It is to be understood that the substrates may consist of sapphire, silicon carbide (SiC), GaN, silicon, quartz, gallium arsenide (GaAs), aluminum nitride (AIN) or glass. A u-GaN followed by an n-type GaN layer 112 may be deposited over a GaN or aluminum nitride (AIN) buffer layer 108 formed over the substrate. An active region of the device is embodied in a multi-quantum-well layer 116, shown in the drawing to comprise an InGaN layer. A p-n junction is formed with an overlying p-type AlGaN layer 120, with a p-type GaN layer 124 acting as a contact layer. The p-type AlGaN layer 120 and the p-type GaN layer 124 may be individually formed according to embodiments described herein.

One example of a fabrication process for such an LED may use a combination of HVPE and/or MOCVD techniques that follow cleaning of the substrate 104 in a processing chamber. In one embodiment, MOCVD deposition is accomplished by providing flows of suitable precursors to the processing chamber and using thermal processes to achieve deposition. For example, a GaN layer may be deposited using Ga and nitrogen containing precursors, perhaps with a flow of a fluent gas like N₂, H₂, and NH₃. In one embodiment, HVPE deposition is used to deposit the GaN layer by flowing a Group III halide vapor formed by reacting a Group III source, such as a gallium (Ga) metal source, with a halide, such as hydrogen chloride (HCl) gas, forming Group III halide vapor.

An InGaN layer may be deposited using Ga, nitrogen containing precursors, and indium (In) precursors, perhaps with a flow of a fluent gas. An AlGaN layer may be deposited using Ga, nitrogen containing precursors, and Al precursors, also perhaps with a flow of a fluent gas. In one embodiment, the GaN buffer layer 108 has a thickness of about 500 Å, and may be deposited at a temperature of about 550 degrees Celsius. Subsequent deposition of the u-GaN and n-GaN layer 112 is typically performed at a higher temperature, such as around 1,050 degrees Celsius in one embodiment. The u-GaN and n-GaN layer 112 is relatively thick, with deposition of a thickness on the order of about 4 μm requiring about 140 minutes for deposition. The InGaN multi-quantum-well (MQW) layer 116 may have a thickness of about 750 Å, which may be deposited over a period of about 40 minutes at a temperature of about 750 degrees Celsius. The p-AlGaN layer 120 may have a thickness of about 200 Å, which may be deposited in about five minutes at a temperature from about 950 degrees Celsius to about 1,020 degrees Celsius. The p-AlGaN layer 120 may be deposited using the embodiments described herein. In one embodiment, the thickness of the contact layer 124 that completes the structure may be about 0.4 μm, and may be deposited at a temperature of about 1,050 degrees Celsius for around 25 minutes. The contact layer 124 may be deposited using the embodiments described herein. Additionally, dopants, such as silicon (Si) or magnesium (Mg), may be added to the films. The films may be doped by adding small amounts of dopant gases during the deposition process. For silicon doping, silane (SiH₄) or disilane (Si₂H₆) gases may be used, for example, and for magnesium doping, the dopant gases may include, for example, Bis(cyclopentadienyl) magnesium (Cp₂Mg or (C₅H₅)₂Mg).

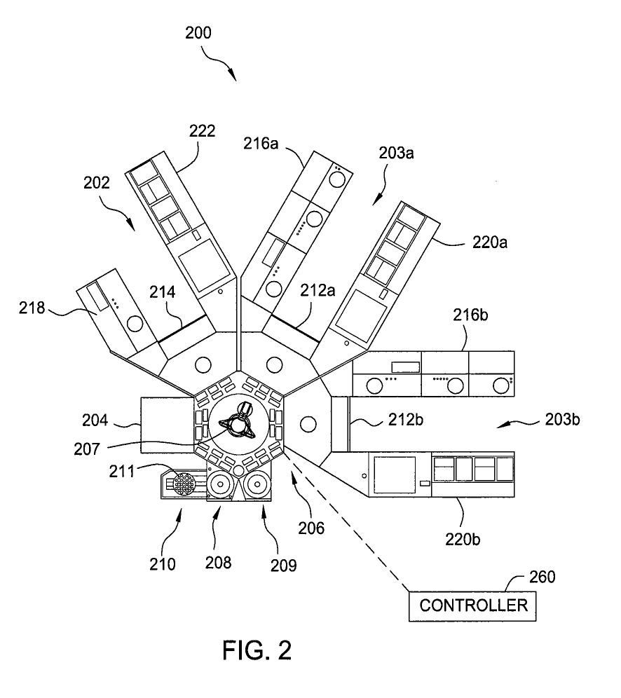

FIG. 2 is a schematic top view illustrating one embodiment of an exemplary processing system 200 comprising one HVPE chamber 202 and multiple MOCVD chamber 203a and 203b for fabricating compound nitride semiconductor devices and performing in-situ activation according to embodiments described herein. In one embodiment, the environment within the processing system 200 is maintained as a vacuum environment or at a pressure below atmospheric pressure. In certain embodiments it may be desirable to backfill the processing system 200 with an inert gas such as nitrogen. Although one HVPE chamber 202 and two MOCVD chambers 203a and 203b are shown, it should be understood that any combination of one or more MOCVD chambers with one or more HVPE chambers may also be coupled with the transfer chamber 206. For example, in one embodiment, the processing system 200 may comprise 3 MOCVD chambers. In another embodiment, the processes described herein may be performed in a single MOCVD chamber. It should also be understood that although a cluster tool is shown, the embodiments described herein may be performed using linear track systems. Exemplary embodiments of a linear track system are described in co-pending U.S. patent application Ser. No. 12/885,139, filed Sep. 17, 2010, and titled APPARATUS AND METHODS FOR FORMING ENERGY STORAGE AND PHOTOVOLTAIC DEVICES IN A LINEAR SYSTEM and U.S. patent application Ser. No. 12/853,409, filed Aug. 10, 2010, published as US2011-0033966, and titled GROWTH OF N-FACE LED WITH INTEGRATED PROCESSING SYSTEM both of which are hereby incorporated by reference in their entirety.

In one embodiment, an additional chamber 204 is coupled with the transfer chamber 206. In one embodiment, the additional chamber 204 comprises an additional processing chamber such as an MOCVD chamber or an HVPE chamber. In another embodiment, the additional chamber 204 may comprise a metrology chamber. In yet another embodiment, the additional chamber 204 may contain pre-processing or post-processing chambers, such as service chambers that are adapted for degassing, orientation, cool down, pretreatment/preclean, annealing and the like.

The HVPE chamber 202 is adapted to perform HVPE processes in which gaseous metal halides are used to epitaxially grow thick layers of compound nitride semiconductor materials on heated substrates. The HVPE chamber 202 comprises a chamber body 214 where a substrate is placed to undergo processing, a chemical delivery module 218 from which gas precursors are delivered to the chamber body 214, and an electrical module 222 that includes the electrical system for the HVPE chamber of the processing system 200.

Each MOCVD chamber 203a, 203b comprises a chamber body 212a, 212b forming a processing region where a substrate is placed to undergo processing, a chemical delivery module 216a, 216b from which gases such as precursors, purge gases, activation gases, and cleaning gases are delivered to the chamber body 212a, 212b and an electrical module 220a, 220b for each MOCVD chamber 203a, 203b that includes the electrical system for each MOCVD chamber of the processing system 200. Each MOCVD chamber 203a, 203b is adapted to perform CVD processes in which metalorganic elements react with metal hydride elements to form thin layers of compound nitride semiconductor materials.

The processing system 200 comprises a transfer chamber 206 housing a robot assembly 207, an HVPE chamber 202, a first MOCVD chamber 203a, and a second MOCVD chamber 203b coupled with the transfer chamber 206, a loadlock chamber 208 coupled with the transfer chamber 206, a batch loadlock chamber 209, for storing substrates, coupled with the transfer chamber 206, and a load station 210, for loading substrates, coupled with the loadlock chamber 208. The robot assembly 207 is operable to pick up and transfer substrates between the loadlock chamber 208, the batch loadlock chamber 209, the HVPE chamber 202, the first MOCVD chamber 203a, and the second MOCVD chamber 203b.

The transfer chamber 206 may remain under vacuum and/or at a pressure below atmosphere during the process. The vacuum level of the transfer chamber 206 may be adjusted to match the vacuum level of corresponding processing chambers. In certain embodiments it may be desirable to backfill the transfer chamber 206 with an inert gas such as nitrogen. In one embodiment, the substrate is transferred in an environment having greater than 90% N₂. In certain embodiments, the substrate is transferred in a high purity NH₃ environment. In one embodiment, the substrate is transferred in an environment having greater than 90% NH₃. In certain embodiments, the substrate is transferred in a high purity H₂ environment. In one embodiment, the substrate is transferred in an environment having greater than 90% H₂.

In the processing system 200, the robot assembly transfers a carrier plate 211 under vacuum loaded with substrates into the HVPE chamber 202 to undergo a first deposition process. In one embodiment, the carrier plate 211 comprises a silicon carbide material. In one embodiment, the carrier plate 211 has a surface area of about 1,000 cm² or more, preferably 2,000 cm² or more, and more preferably 4,000 cm² or more. Exemplary embodiments of the carrier plate are further described in U.S. patent application Ser. No. 12/871,143, filed Aug. 30, 2010, and titled SUBSTRATE CARRIER DESIGN FOR IMPROVED PHOTOLUMINESCENCE UNIFORMITY which is hereby incorporated by reference in its entirety. The robot assembly transfers the carrier plate 211 under vacuum into the first MOCVD chamber 203a to undergo a second deposition process. The robot assembly transfers the carrier plate 211 under vacuum into the second MOCVD chamber 203b to undergo a third deposition process. After all or some of the deposition steps have been completed, the carrier plate 211 is transferred from either the HVPE chamber 202 or one of the MOCVD chambers 203a, 203b back to the loadlock chamber 208. In one embodiment, the carrier plate 211 is then released toward the load station 210. In another embodiment, the carrier plate 211 may be stored in either the loadlock chamber 208 or the batch load lock chamber 209 prior to further processing in the HVPE chamber 202 or MOCVD chambers 203a, 203b. One exemplary system is described in U.S. patent application Ser. No. 12/023,572, filed Jan. 31, 2008, now published as US 2009-0194026, and titled PROCESSING SYSTEM FOR FABRICATING COMPOUND NITRIDE SEMICONDUCTOR DEVICES, which is hereby incorporated by reference in its entirety.

A system controller 260 controls activities and operating parameters of the processing system 200. The system controller 260 includes a computer processor and a computer-readable memory coupled to the processor. The processor executes system control software, such as a computer program stored in memory. Aspects of the processing system and methods of use are further described in U.S. patent application Ser. No. 11/404,516, filed Apr. 14, 2006, now published as US 2007-024,516, and titled EPITAXIAL GROWTH OF COMPOUND NITRIDE STRUCTURES, which is hereby incorporated by reference in its entirety.

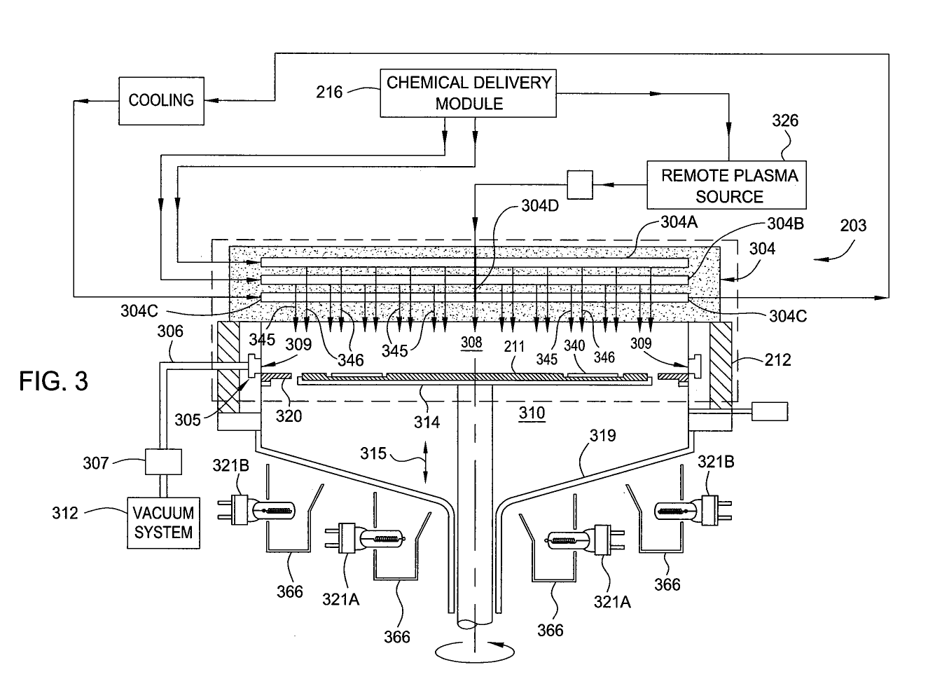

FIG. 3 is a schematic cross-sectional view of an MOCVD chamber 203 (also referred to herein as 203a and 203b) adapted to deposit a Group III-nitride film and perform in-situ acceptor activation according to embodiments described herein. The MOCVD chamber 203 comprises a chamber body 212, a chemical delivery module 216 for delivering precursor gases, carrier gases, cleaning gases, and/or purge gases, a remote plasma system 326 with a plasma source for performing in-situ acceptor activation, a susceptor or substrate support 314, and a vacuum system 312. The chamber 203 includes a chamber body 212 that encloses a processing volume 308. A showerhead assembly 304 is disposed at one end of the processing volume 308, and the carrier plate 211 is disposed at the other end of the processing volume 308. The carrier plate 211 may be disposed on the substrate support 314. The substrate support 314 has z-lift capability for moving in a vertical direction, as shown by arrow 315. In one embodiment, the z-lift capability may be used to move the substrate support both upward and closer to the showerhead assembly 304 or downward and further away from the showerhead assembly 304. In certain embodiments, the substrate support 314 comprises a heating element, for example, a resistive heating element (not shown) for controlling the temperature of the substrate support 314 and consequently controlling the temperature of the carrier plate 211 and substrates 340 positioned on the substrate support 314.

In one embodiment, the showerhead assembly 304 has a first processing gas channel 304A coupled with the chemical delivery module 216 for delivering a first precursor or first process gas mixture to the processing volume 308, a second processing gas channel 304B coupled with the chemical delivery module 216 for delivering a second precursor or second process gas mixture to the processing volume 308 and a temperature control channel 304C coupled with a heat exchanging system 370 for flowing a heat exchanging fluid to the showerhead assembly 304 to help regulate the temperature of the showerhead assembly 304. Suitable heat exchanging fluids include but are not limited to water, water-based ethylene glycol mixtures, a perfluoropolyether (e.g., GALDEN® perfluoropolyether fluid), oil-based thermal transfer fluids, or similar fluids. In one embodiment, during processing the first precursor or first process gas mixture may be delivered to the processing volume 308 via gas conduits 346 coupled with the first processing gas channel 304A in the showerhead assembly 304 and the second precursor or second process gas mixture may be delivered to the processing volume 308 via gas conduits 345 coupled with the second processing gas channel 304B. In embodiments where the remote plasma system 326 is used, the plasma may be delivered to the processing volume 308 via conduit 304D. It should be noted that the process gas mixtures or precursors may comprise one or more precursor gases or process gases as well as carrier gases and dopant gases which may be mixed with the precursor gases. Exemplary showerheads that may be adapted to practice embodiments described herein are described in U.S. patent application Ser. No. 11/873,132, filed Oct. 16, 2007, published as US2009-0098276, and titled MULTI-GAS STRAIGHT CHANNEL SHOWERHEAD, U.S. patent application Ser. No. 11/873,141, filed Oct. 16, 2007, published as US2009-0095222, and titled MULTI-GAS SPIRAL CHANNEL SHOWERHEAD, and U.S. patent application Ser. No. 11/873,170, filed Oct. 16, 2007, published as US2009-0095221, and titled MULTI-GAS CONCENTRIC INJECTION SHOWERHEAD, all of which are incorporated by reference in their entireties.

A lower dome 319 is disposed at one end of a lower volume 310, and the carrier plate 211 may be disposed at the other end of the lower volume 310. The carrier plate 211 is shown in process position, but may be moved to a lower position where, for example, the substrates 340 may be loaded or unloaded. An exhaust ring 320 may be disposed around the periphery of the carrier plate 211 to help prevent deposition from occurring in the lower volume 310 and also help direct exhaust gases from the chamber 203 to exhaust ports 309. The lower dome 319 may be made of transparent material, such as high-purity quartz, to allow light to pass through for radiant heating of the substrates 340. The radiant heating may be provided by a plurality of inner lamps 321A and outer lamps 321B disposed below the lower dome 319 and reflectors 366 may be used to help control the chamber 203 exposure to the radiant energy provided by inner and outer lamps 321A, 321B. Additional rings of lamps may also be used for finer temperature control of the substrates 340.

In certain embodiments, a purge gas (e.g., a nitrogen containing gas) may be delivered into the chamber 203 from the showerhead assembly 304 and/or from inlet ports or tubes (not shown) disposed below the carrier plate 211 and near the bottom of the chamber body 212. The purge gas enters the lower volume 310 of the chamber 203 and flows upwards past the carrier plate 211 and exhaust ring 320 and into multiple exhaust ports 309 which are disposed around an annular exhaust channel 305. An exhaust conduit 306 connects the annular exhaust channel 305 to a vacuum system 312 which includes a vacuum pump 307. The chamber 203 pressure may be controlled using a valve system which controls the rate at which the exhaust gases are drawn from the annular exhaust channel. Other aspects of the MOCVD chamber 203 are described in U.S. patent application Ser. No. 12/023,520, filed Jan. 31, 2008, published as US2009-0194024, and titled CVD APPARATUS, which is herein incorporated by reference in its entirety.

The chemical delivery module 216 supplies chemicals to the MOCVD chamber 203. Reactive gases, carrier gases, purge gases, annealing gases, and cleaning gases are supplied from the chemical delivery system through supply lines and into the chamber 203. In one embodiment, the gases are supplied through supply lines and into a gas mixing box where they are mixed together and delivered to showerhead assembly 304. In another embodiment, the gases are delivered to the showerhead assembly 304 through separate supply lines and mixed within the chamber 203. In one embodiment, the chemical delivery module 216 contains a nitrogen gas source for supplying a nitrogen containing gas to the remote plasma system 326. In one embodiment, the chemical delivery module 216 contains an oxygen gas source for supplying an oxygen containing gas to the remote plasma system 326. In one embodiment, the chemical delivery module 216 contains an oxygen gas source for supplying an oxygen containing gas to the MOCVD chamber for an annealing process.

Generally, supply lines for each of the gases include shut-off valves that can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback, backpressure regulators may be included to control precursor gas concentrations, valve switching control may be used for quick and accurate valve switching capability, moisture sensors in the gas lines measure water levels and can provide feedback to the system software which in turn can provide warnings/alerts to operators. The gas lines may also be heated to prevent precursors and cleaning gases from condensing in the supply lines. Depending upon the process used some of the sources may be liquid rather than gas. When liquid sources are used, the chemical delivery module includes a liquid injection system or other appropriate mechanism (e.g. a bubbler) to vaporize the liquid. Vapor from the liquids is then usually mixed with a carrier gas as would be understood by a person of skill in the art.

The remote plasma system 326 can produce plasma for selected applications, such as the in-situ acceptor activation described herein. Plasma species produced in the remote plasma system 326 from precursors supplied via an input line are sent via a conduit for dispersion through the showerhead assembly 304 to the MOCVD chamber 203. Precursor gases for the in-situ acceptor activation include nitrogen containing gases, oxygen containing gases and/or other reactive elements. In one embodiment, the remote plasma system 326 is used to deliver active nitrogen species to the processing volume 308.

It should be understood that the MOCVD chamber 203 may be modified to accommodate and process substrates in an in-line conveyor processing system, by modifying the chamber to include a conveyor.

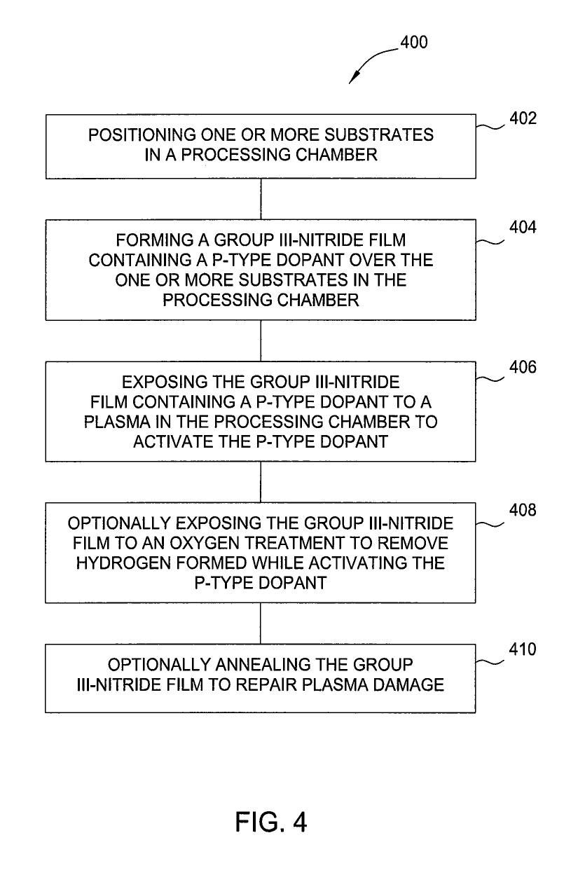

FIG. 4 is a flow diagram of one embodiment of an in-situ acceptor activation process 400 that may be used for an in-situ acceptor activation process with either nitrogen and/or oxygen plasma treatment. In one embodiment, the in-situ acceptor activation process 400 may be performed in a single chamber, such as MOCVD chamber 203. In another embodiment, the in-situ acceptor activation process 400 may be performed in the various chambers of a cluster tool in a vacuum environment, such as cluster tool 200. In certain embodiments, the in-situ acceptor activation process 400 may be used to form the p-doped layers of the LED structure depicted in FIG. 1.

At block 402, one or more substrates are positioned in a processing chamber. In certain embodiments, the one or more substrates may have any number of layers already deposited thereon, for example, buffer layer 108, U-GaN+n-GaN layer 112, and InGaN MQW 116. In one embodiment, where the substrate processing chamber is the MOCVD chamber 203a, the carrier plate 211 containing one or more substrates 340 is transferred into the MOCVD chamber 203a.

As shown at block 404, a Group III-nitride film containing a p-type dopant is formed over the one or more substrates in the processing chamber. In one embodiment, the Group III-nitride film is selected from the group comprising GaN, InGaN, AlGaN, AllnGaN, and combinations thereof. The embodiments described herein may also be used for other Group III-V compound semiconductors, in which the doping acceptor species exhibit the phenomena of H₂-passivation. In one embodiment, the p-type dopant may be selected from the group comprising, consisting of, or consisting essentially of magnesium (Mg), zinc (Zn), cadmium (Cd), calcium (Ca), beryllium (Be), strontium (Sr), barium (Ba), radium (Ra), and combinations thereof. In embodiments where the p-type dopant is Mg, the magnesium precursor may be Bis(cyclopentadienyl) magnesium (Cp₂Mg or (C₅H₅)₂Mg). In embodiments where the p-type dopant is Zn, the zinc precursor may be diethylzinc (DEZ). In one embodiment, the p-type dopant is magnesium and the Group III-nitride film is GaN. In one embodiment, the Group III-nitride film containing a p-type dopant is the p-GaN layer 124 depicted in FIG. 1. In one embodiment, the Group III-nitride film containing a p-type dopant is the p-AlGaN layer 120 depicted in FIG. 1.

At block 406, the Group III-nitride film containing a p-type dopant is exposed to a plasma in the processing chamber to activate the p-type dopant. In one embodiment, the plasma is a nitrogen containing plasma. In one embodiment, the plasma is an oxygen containing plasma. The plasma may be formed from a gas source selected from the group consisting of: O₂, N₂, O₂/N₂, N₂O, NO, and combinations thereof. In one embodiment, the plasma is formed by a remote plasma source, such as remote plasma system 326, and delivered to the processing chamber, such as processing chamber 203a, where the plasma treatment process is performed. In one embodiment, the remote plasma system 326 comprises a power source coupled with a chamber.

In one embodiment, the power source is a 2.54 GHz microwave energy source. In embodiments, where a microwave source is used to activate the precursor gas, the microwave source delivers about 3,000-12,000 Watts to the remote activation chamber. A value of 5,000 Watts may be used for many applications. In certain embodiments, the power in the present disclosure is expressed as Watts supplied to an electrode per substrate area. In one embodiment, the microwave source delivers about 0.75 W/cm² to about 3 W/cm² to the remote activation chamber. In one embodiment, the microwave source delivers about 1.25 W/cm² to the remote activation chamber.

In one embodiment, the power source is an RF power source. Various RF frequencies may be used, such as a frequency between about 0.3 MHz and about 200 MHz. In one embodiment the RF power source is provided at a frequency of 13.56 MHz. In one embodiment, the plasma is capacitively coupled plasma. In one embodiment, the plasma is inductively coupled plasma. In embodiments where an RF power source is used to activate the precursor gas, the RF power source may deliver about 3,000-12,000 Watts to the remote activation chamber. In one embodiment, the RF power source delivers about 0.75 W/cm² to about 3 W/cm² to the remote activation chamber. In one embodiment, the RF source delivers about 1.25 W/cm² to the remote activation chamber.

Optionally, there may also be a carrier gas source that is coupled with the remote plasma system 326 for transporting the activated plasma species to the MOCVD chamber 203. It can be any appropriate nonreactive gas that is compatible with the particular process with which it is being used. For example, the carrier gas may be selected from the group comprising, consisting of, or consisting essentially of argon, nitrogen, helium, hydrogen, oxygen, and combinations thereof. In addition to aiding in the transport of activated species to the deposition chamber, the carrier gas may also help initiate and/or stabilize the plasma in the deposition chamber.

The flow rate of activated species into the MOCVD chamber 203 may be between about 1,000 sccm and about 20,000 sccm. In one embodiment, the flow rate of activated species is about 2,000 sccm. In certain embodiments, the flow rates in the present disclosure are expressed as sccm per interior chamber volume. The interior chamber volume is defined as the volume of the interior of the chamber in which a gas can occupy. For example, the interior chamber volume of chamber 203 is the volume defined by the chamber body 212 minus the volume occupied therein by the showerhead assembly 304 and by the substrate support assembly 314. In one embodiment, the flow rate of the activated species in the MOCVD chamber 203 may be between about 25 sccm/L and about 500 sccm/L. In one embodiment, the flow rate of activated species is about 50 sccm/L. The pressure in the MOCVD chamber 203 may be maintained at between about 0.01 Torr and about 10 Torr. In one embodiment, the pressure in the MOCVD chamber 203 is maintained at about 2 Torr. In one embodiment, the pressure in the MOCVD chamber 203 is maintained at about 0.5 Torr.

In one embodiment, during the plasma treatment process, the one or more substrates are maintained at a temperature between about 100 degrees Celsius and about 700 degrees Celsius. In one embodiment, the substrates are maintained at a temperature of about 200 degrees Celsius. In one embodiment, the one or more substrates are exposed to the plasma for a time period of between 1 minute and about 30 minutes. In one embodiment, the one or more substrates are exposed to the plasma for a time period between 10 minutes and about 20 minutes.

At block 408, after exposure of the Group III-nitride film containing a p-type dopant to the nitrogen plasma, the Group III-nitride film may optionally be exposed to an oxygen treatment process to remove hydrogen from the processing chamber.

In one embodiment, the oxygen treatment process comprises exposing the Group III-nitride film to oxygen containing plasma which may be formed using the process conditions described above in block 406 with reference to the plasma treatment.

In one embodiment, the oxygen treatment process comprises exposing the Group III-nitride film to an annealing process, such as a thermal annealing process in an oxygen containing environment. Oxygen containing gas sources include oxidizing agents (or an oxygen comprising agent) such as O₂, O₂/N₂, O₂/Ar, O₂/He, N₂O, NO and combinations thereof.

In certain embodiments where the oxygen treatment process is a thermal annealing process, the substrate temperature is maintained at a temperature between about 200 degrees Celsius and about 400 degrees Celsius, such as about 250 degrees Celsius. In one embodiment, the thermal annealing process is performed for a time period between about 1 minute and about 30 minutes. In one embodiment, the thermal annealing process is performed for a time period between about 10 minutes and about 20 minutes. In one embodiment, the pressure of the MOCVD chamber is maintained from about 100 mTorr to about 800 Torr. Oxygen may be flown into the chamber at a flow rate between about 1,000 sccm and about 20,000 sccm. In one embodiment, the flow rate of oxygen species in the MOCVD chamber 203 may be between about 25 sccm/L and about 500 sccm/L. It is believed that the presence of oxygen in the MOCVD chamber combines with hydrogen liberated by the nitrogen containing plasma treatment process to form H₂O which may be removed from the chamber.

At block 410, the Group III-nitride film may be exposed to an annealing process to repair plasma damage of the film which may have occurred during the previous plasma treatment processes.

### EXAMPLES

The following hypothetical non-limiting examples are provided to further illustrate embodiments described herein. However, the examples are not intended to be all inclusive and are not intended to limit the scope of the embodiments described herein.

### Example 1

A sapphire substrate was positioned in an MOCVD chamber. A magnesium doped GaN film was deposited over the sapphire substrate. The magnesium doped GaN film was subsequently exposed to plasma activated nitrogen species formed by a remote inductively coupled plasma coupled with the MOCVD chamber to break Mg—H bonds. The plasma activated nitrogen species was flown into the MOCVD chamber at flow rate of about 50 sccm/L while the MOCVD chamber pressure was maintained at about 0.5 Torr for a time period of about 5 minutes and the substrate temperature was about 200 degrees Celsius. The magnesium doped GaN film was subsequently exposed to a thermal annealing process in an oxygen containing environment in the MOCVD chamber to remove residual hydrogen liberated from the nitrogen containing plasma treatment.

### Example 2

A sapphire substrate was positioned in an MOCVD chamber. A magnesium doped GaN film was deposited over the sapphire substrate. The magnesium doped GaN film was subsequently exposed to plasma activated nitrogen species formed by a remote inductively coupled plasma coupled with the MOCVD chamber to break Mg—H bonds. The plasma activated nitrogen species was flown into the MOCVD chamber at flow rate of about 250 sccm/L while the MOCVD chamber pressure was maintained at about 0.5 Torr for a time period of about 10 minutes and the substrate temperature was about 250 degrees Celsius. The magnesium doped GaN film was subsequently exposed to an oxygen containing plasma in the MOCVD chamber to remove residual hydrogen liberated from the nitrogen containing plasma treatment. The plasma activated oxygen species was flown into the MOCVD chamber at flow rate of about 125 sccm/L while the MOCVD chamber pressure was maintained at about 0.5 Torr for a time period of about 5 minutes and the substrate temperature was about 250 degrees Celsius.

It should be understood that the sapphire substrates discussed in Example 1 and Example 2 may already have a partial LED structure deposited thereon. For example, the magnesium doped GaN film may be deposited over an InGaN MQW layer.

While the foregoing is directed to embodiments of the present invention, other and further embodiments of the invention may be devised without departing from the basic scope thereof, and the scope thereof is determined by the claims that follow.

1. A method for fabricating a compound nitride structure on a substrate, comprising:
depositing a p-type doped Group III-nitride film over one or more substrates in a processing chamber; and
exposing the p-type doped Group III-nitride film to a plasma in the processing chamber to activate the p-type dopant by breaking up hydride complexes formed between the p-type dopant and hydrogen.

2. The method of claim 1, wherein the plasma is formed from a gas source selected from the group consisting of: O₂, N₂, O₂/N₂, N₂O, NO, and combinations thereof.

3. The method of claim 2, wherein the plasma is formed by an inductively coupled remote plasma source and delivered to the processing chamber.

4. The method of claim 1, wherein the Group III-nitride is a gallium nitride (GaN) film further comprising an additional Group III element selected from the group comprising: aluminum, indium, and combinations thereof.

5. The method of claim 4, wherein the p-type dopant is magnesium.

6. The method of claim 1, further comprising exposing the plasma treated p-type doped Group III-nitride film to an oxygen containing gas to remove hydrogen liberated by breaking up hydride complexes formed between the p-type dopant and hydrogen.

7. The method of claim 6, wherein the exposing the plasma treated p-type doped Group III-nitride film to an oxygen containing gas comprises thermal annealing the plasma treated p-type doped Group III-nitride film in an oxygen containing environment containing an oxygen containing gas source selected from the group consisting of: O₂, O₂/N₂, O₂/Ar, O₂/He, N₂O, NO, and combinations thereof.

8. The method of claim 6, wherein the exposing the plasma treated p-type doped Group III-nitride film to an oxygen containing gas comprises exposing the plasma treated p-type doped Group III-nitride film to an oxygen containing plasma.

9. The method of claim 6, further comprising annealing the Group III-nitride film in a nitrogen containing environment to repair plasma damage to the Group III-nitride film.

10. A method for fabricating a compound nitride structure on a substrate, comprising:
depositing a magnesium doped gallium nitride (GaN) film over one or more substrates in a metal organic chemical vapor deposition (MOCVD) chamber; and
exposing the magnesium doped GaN film to a nitrogen containing plasma in the MOCVD chamber to activate the magnesium dopant by breaking up magnesium-hydride complexes formed between magnesium and hydrogen.

11. The method of claim 10, wherein the nitrogen containing plasma is formed by an inductively coupled remote plasma source and delivered to the processing chamber.

12. The method of claim 10, wherein the GaN film further comprises an additional Group III element selected from the group comprising: aluminum, indium, and combinations thereof.

13. The method of claim 10, further comprising exposing the plasma treated magnesium doped GaN film to an oxygen containing gas to remove hydrogen liberated by breaking up magnesium-hydride complexes formed between magnesium and hydrogen.

14. The method of claim 10, wherein the nitrogen containing plasma is a remotely formed inductively coupled plasma that is flown into the MOCVD chamber at a flow rate between about 25 sccm/L and about 500 sccm/L, at a MOCVD chamber pressure between about 0.01 Torr and about 10 Torr, and at a substrate temperature between about 100° C. and about 700° C.

15. The method of claim 14, wherein the flow rate is about 50 sccm/L, the MOCVD chamber pressure is about 0.5 Torr, and the substrate temperature is about 200° C.

16. The method of claim 13, wherein the oxygen treatment process comprises exposing the GaN film to an oxygen containing plasma.

17. The method of claim 13, wherein the oxygen treatment process comprises exposing the GaN film to a thermal annealing process in an environment containing gases selected from the group consisting of: O₂, O₂/N₂, O₂/Ar, O₂/He, N₂O, NO, and combinations thereof.

18. An integrated processing system for fabricating a compound nitride structure on a substrate, comprising:
a transfer chamber;
a robot assembly disposed in the transfer chamber for transferring one or more substrates without exposing the one or more substrates to atmosphere;
a metal organic chemical vapor deposition (MOCVD) chamber in transferable communication with the transfer chamber and operable to form a p-type doped Group III-nitride film over the one or more substrates with a thermal chemical-vapor-deposition process; and
a remote plasma source coupled with the MOCVD chamber for delivering a nitrogen containing plasma to the MOCVD chamber to activate the p-type dopant by breaking up hydride complexes formed between the p-type dopant and hydrogen.

19. The integrated processing system of claim 18, further comprising:
an oxygen containing gas source coupled with the MOCVD chamber operable for flowing an oxygen containing gas into the MOCVD chamber for performing a thermal annealing process in an environment containing gases selected from the group consisting of: O₂, O₂/N₂, O₂/Ar, O₂/He, N₂O, NO, and combinations thereof.

20. The integrated processing system of claim 18, further comprising:
an oxygen containing gas source coupled with the remote plasma source for flowing an oxygen containing plasma into the MOCVD chamber for performing a plasma treatment of the p-type doped Group III-nitride film.
